(19) United States
(12) Patent Application Publication
(10) Pub. No.: US 2026/0181962 A1
(43) Pub. Date: Jun. 25, 2026

(54) THIN FILM TRANSISTOR AND ELECTRONIC DEVICE

(71) Applicant: WUHAN CHINA STAR OPTOELECTRONICS TECHNOLOGY CO., LTD., Wuhan, Hubei (CN)

(72) Inventors: Fei AI, Wuhan, Hubei (CN); Zhuang LI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/843,246

(22) PCT Filed: Nov. 20, 2023
(86) PCT No.: PCT/CN2023/132511

§ 371 Date: Aug. 31, 2024

(30) Foreign Application Priority Data
Sep. 5, 2023 (CN) 202311141557.2

(51) Int. Cl. H10D 30/67

(52) U.S. Cl. CPC H10D 30/6757; H10D 30/6758

(57) ABSTRACT

The present application provides a thin film transistor and an electronic device. the thin film transistor disposes an effective part on a sidewall of a barrier layer, and enables a second electrode to extend through a channel layer and contact a second ohmic contact layer, and/or enables the first electrode to extend through the barrier layer and contact the first ohmic contact layer, or enables the first electrode to extend through the channel layer and contact the first ohmic contact layer, thereby being able to improve a yield of the display panel and reducing a size of the thin film transistor.

### FIELD OF INVENTION

The present application relates to a field of display technologies, especially to a thin film transistor and an electronic device.

### BACKGROUND OF INVENTION

Integrating circuits such as the pixel driver circuit, gate electrode driver circuit, source electrode driver circuit, and timing controller on a glass substrate (system on glass, SOG) can significantly increase the integration level of the display panel and reduce dependence on integrated circuit chips, thereby lowering costs. To achieve SOG, it is necessary to enhance the integration density, maximum working frequency, and current density of thin film transistors in conventional display panels. These requirements necessitate thin film transistors with shorter channel lengths, higher mobility, and smaller volume.

To reduce the channel length in conventional display devices, a vertical structure for thin film transistors is designed. By depositing the channel on the side surface of a boss and placing contact layers above and below the boss, the channel length is determined by the distance between the upper and lower contact layers and the angle of the boss. This allows the channel length to be controlled by adjusting the thickness and angle of the boss. In conventional processes, the thickness and angle of the boss are relatively easy to control (with precision up to less than 1 micron), which helps reduce the channel length and increase mobility. However, this design requires extending two contact layers beyond the channel to connect to the source and drain electrode layers. In the actual manufacturing process, it has been found that the process of retaining the two contact layers while etching the channel is quite difficult. It is easy to accidentally etch away parts of the contact layers that extend beyond the channel when etching the channel itself, causing the thin film transistor to fail to function properly, leading to a low yield of thin film transistors and display panels.

Therefore, conventional display devices face a technical issue where the contact layers are easily etched away when etching the channel of a vertical structure thin film transistor, resulting in a lower yield of display panels.

### SUMMARY OF INVENTION

An embodiment of the present application provides a thin film transistor and an electronic device to solve the technical issue where the contact layers are easily etched away when etching the channel of a vertical structure thin film transistor, resulting in a lower yield of display panels.

To solve the above issue, a technical solution provided by the present application is as follows:

The embodiment of the present application provides a thin film transistor, the thin film transistor comprises:
an underlay substrate;
a first ohmic contact layer disposed on a side of the underlay substrate;
a barrier layer disposed on a side of the first ohmic contact layer away from the underlay substrate, wherein the barrier layer comprises at least one sidewall;
a second ohmic contact layer disposed on a side of the barrier layer away from the first ohmic contact layer;
a channel layer comprising a first connection part, a second connection part, and an effective part located on the sidewall, wherein the first connection part contacts the first ohmic contact layer, and the second connection part is disposed on the second ohmic contact layer;
a gate electrode insulation layer disposed on a side of the channel layer away from the second ohmic contact layer;
a gate electrode layer disposed on a side of the gate electrode insulation layer away from the channel layer, wherein an orthographic projection of the gate electrode layer along a direction perpendicular to the underlay substrate direction covers the effective part;
an interlayer insulation layer disposed on a side of the gate electrode layer away from the gate electrode insulation layer;
a source and drain electrode layer disposed on a side of the interlayer insulation layer away from the gate electrode layer, wherein the source and drain electrode layer comprises a first electrode and a second electrode;
wherein the second electrode extends through the channel layer and contacts the second ohmic contact layer;
and/or, the first electrode extends through the barrier layer and contacts the first ohmic contact layer;
or, the first connection part is disposed on the first ohmic contact layer, and the first electrode extends through the channel layer and contacts the first ohmic contact layer.

Also, the embodiment of the present application provides an electronic device, the electronic device comprises any one of the thin film transistors of the above embodiment.

### DESCRIPTION OF DRAWINGS

Specific embodiments of the present invention are described in detail with accompanying drawings as follows to make technical solutions and advantages of the present invention clear.

FIG. 1 is a see-through view of a conventional display panel.

FIG. 2 is a cross-sectional view along the display panel a line B1-B2 in FIG. 1.

FIG. 3 is a cross-sectional view of the display panel along a line A1-A2 in FIG. 1.

FIG. 4 is a top view of a first film layer structure of a thin film transistor provided by the embodiment of the present application.

FIG. 5 is an exploded view of each film layer of the thin film transistor in FIG. 4.

FIG. 6 is a first cross-sectional view of the thin film transistor along a line B1-B2 in FIG. 4.

FIG. 7 is a cross-sectional view of the thin film transistor along a line A1-A2 in FIG. 4.

FIG. 8 is a top view of a second film layer structure of the thin film transistor provided by the embodiment of the present application.

FIG. 9 is an exploded view of each film layer of the thin film transistor in FIG. 8.

FIG. 10 is a cross-sectional view of the thin film transistor along a line B1-B2 in FIG. 8.

FIG. 11 is a second cross-sectional view of the thin film transistor along the line B1-B2 in FIG. 4.

FIG. 12 is a schematic view of the structure of the film transistor corresponding to each step of the thin film transistor manufacturing method in FIG. 4.

FIG. 13 is a schematic view of the structure of the film transistor corresponding to each step of the thin film transistor manufacturing method in FIG. 8.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application.

In the description of the present application, it should be understood that terminologies of “center”, “longitudinal”, “transverse”, “length”, “width”, “thickness”, “upper”, “lower”, “front”, “rear”, “left”, “side”, “vertical”, “horizontal”, “top”, “bottom”, “inner”, “outer”, “clockwise”, “counterclockwise” for indicating relations of orientation or position are based on orientation or position of the accompanying drawings, are only for the purposes of facilitating description of the present application and simplifying the description instead of indicating or implying that the referred device or element must have a specific orientation or position, must to be structured and operated with the specific orientation or position. Therefore, they should not be understood as limitations to the present application. Furthermore, terminologies “first”, “second” are only for the purposes of description, and cannot be understood as indication or implication of comparative importance or a number of technical features. Therefore, a feature limited with “first”, “second” can expressly or implicitly include one or more features. In the description of the present application, a meaning of “a plurality of” is two or more, unless there is a clear and specific limitation otherwise.

In the description of the present application, it should be noted that unless clear rules and limitations otherwise exist, terminologies “install”, “connect”, “connection” should be understood in a broad sense. For instance, the connection can be a fixed connection, a detachable connection or an integral connection. The connection can be a mechanical connection, an electrical connection or a telecommunication. The connection can be a direct connection, an indirect connection through an intermedium, can be an internal communication between two elements or an interaction between the two elements. For a person of ordinary skill in the art, the specific meaning of the above terminology in the present application can be understood on a case-by-case basis.

In the present application, it should be noted that unless clear rules and limitations otherwise exist, words “a first feature is “on” or “under” a second feature” can include a direct contact of the first and second features, can also include a contact of the first and second features through another feature therebetween instead of a direct contact. Furthermore, words “the first feature is “above” or “over” the second feature include that the first feature is right above or obliquely above the second feature, or only indicate that a level of the first feature is higher that of the second feature. Words “the first feature is “under” or “below” the second feature include that the first feature is right under or obliquely under the second feature, or only indicate that the level of the first feature is lower than that of the second feature.

The following disclosure provides many different embodiments or examples to achieve different structures of the present application. To simplify the disclosure of the present application, the components and arrangements of the specific examples are described below. Of course, they are merely examples, and the purpose is not to limit the present application. Furthermore, the present application may repeat reference numerals and/or reference letters in different examples. The repetition is for the purpose of simplification and clarity, and does not by itself indicate the relationship between the various embodiments and/or settings discussed. In addition, the present application provides examples of various specific processes and materials, but a person of ordinary skill in the art can be aware of the application of other processes and/or the use of other materials.

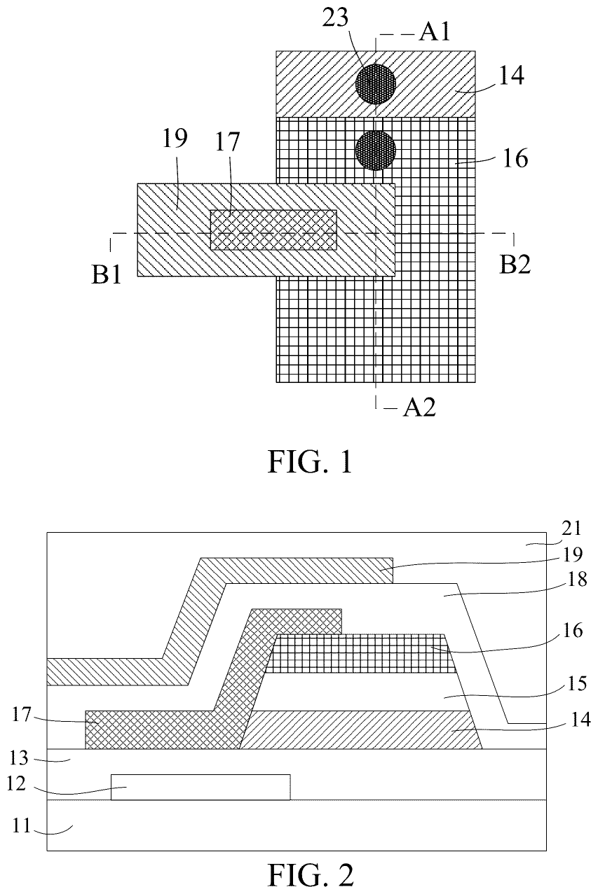

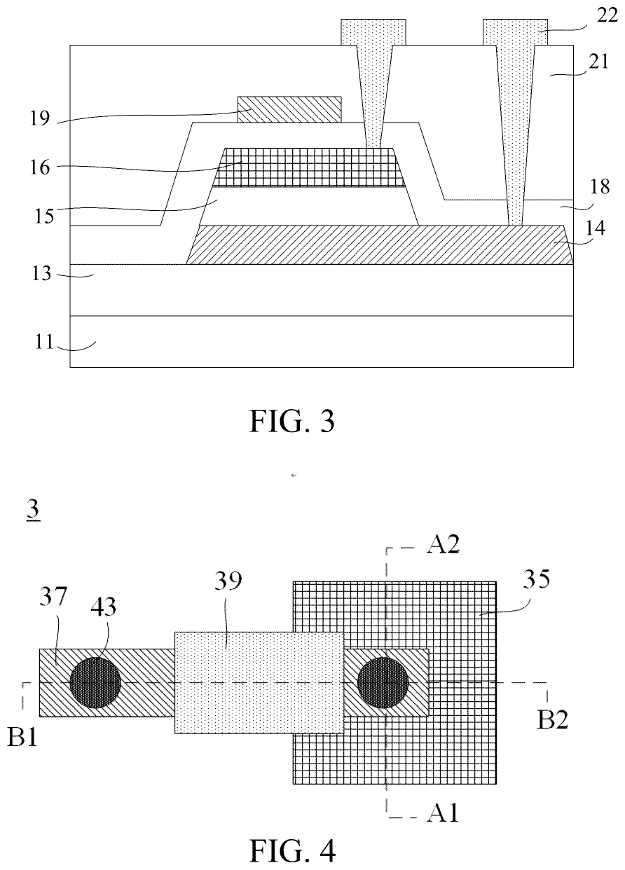

FIG. 1 is a see-through view of a conventional display panel. FIG. 2 is a cross-sectional view along the display panel a line B1-B2 in FIG. 1. FIG. 3 is a cross-sectional view of the display panel along a line A1-A2 in FIG. 1.

With reference to FIG. 1 to FIG. 3, a reference numeral 23 refers to a location of a hole, a display panel of a conventional vertical structure comprises a base 11, a light shielding metal 12, a buffer material 13, a first contact layer 14, a boss 15, a second contact layer 16, a channel 17, a first insulation layer 18, a gate electrode 19, a second insulation layer 21, and a source and drain electrode layer 22. It can be seen from FIG. 2 that the channel 17 is disposed on a side surface of the boss 15, and the first contact layer 14 and the second contact layer 16, are disposed on a top and a bottom of the boss 15 such that the channel length can be controlled by a thickness of the boss 15 and an of the boss 15. The thickness of the boss 15 under the conventional process can easily be controlled to 1 microns or less such that the channel length is smaller, thereby improving the mobility. However, it can bee seen from FIG. 1 to FIG. 3 that to make a source electrode and a drain electrode in the source and drain electrode layer 22 connected respectively to the first contact layer 14 and the second contact layer 16, the first contact layer 14 and the second contact layer 16 need to be reserved during etching the channel 17, thereby resulting in greater process difficulty. The first contact layer 14 and the second contact layer 16 are easily etched out during etching the channel 17, thereby resulting in the source and drain electrode layer 22 unable to be connected to the first contact layer 14 and the second contact layer 16 to cause a lower yield of the thin film transistor and a lower yield of the display panel. Therefore, the conventional display device has a technical issue that during etching a channel of the vertical structure thin film transistor, a contact layer is easily etched out and results in a lower yield of the display panel.

The embodiment of the present application aims at the above technical issue, provides a thin film transistor and a display panel to solve the above technical issue.

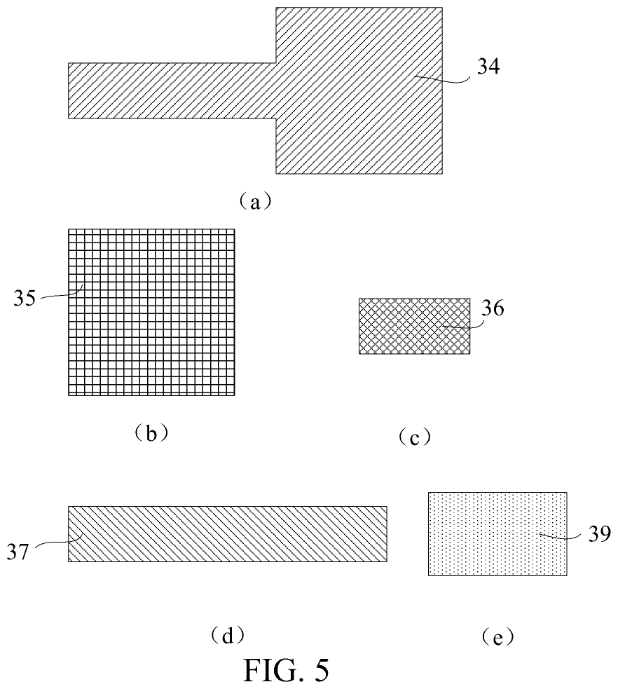

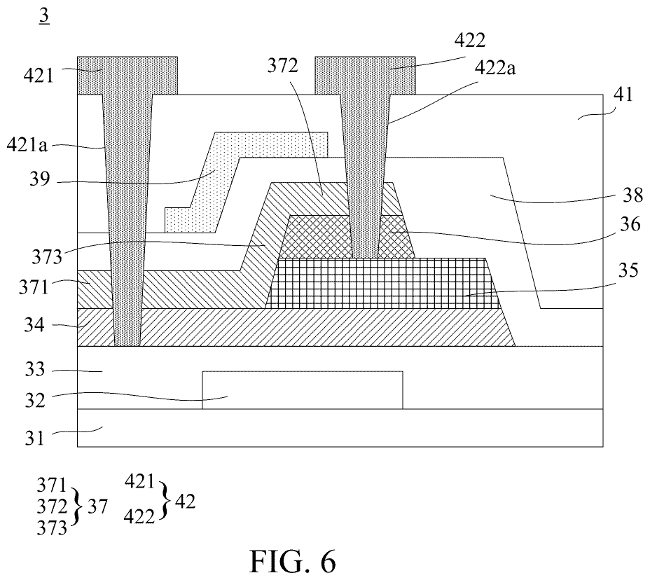

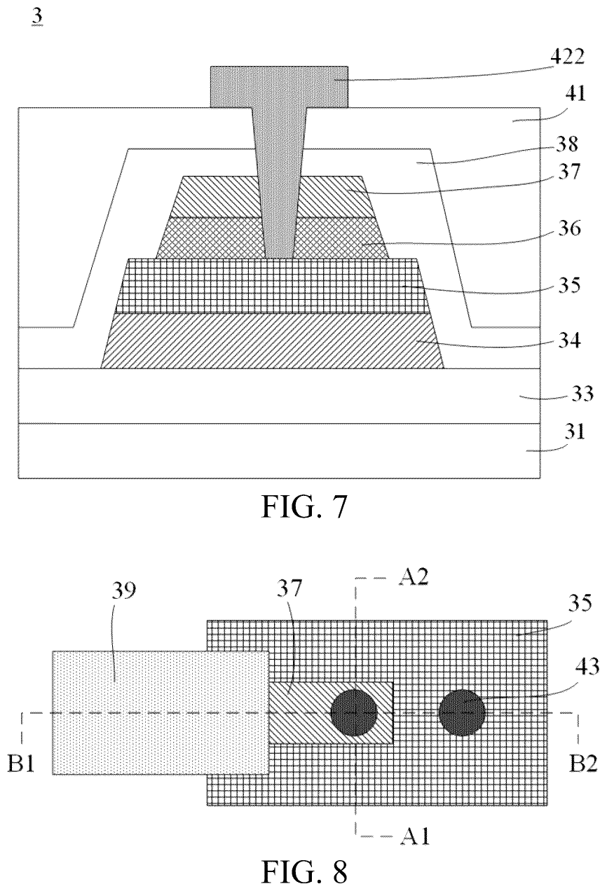

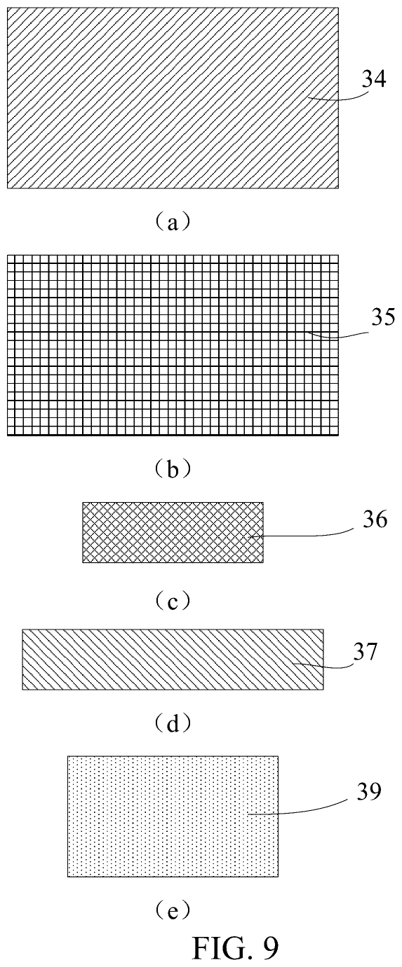

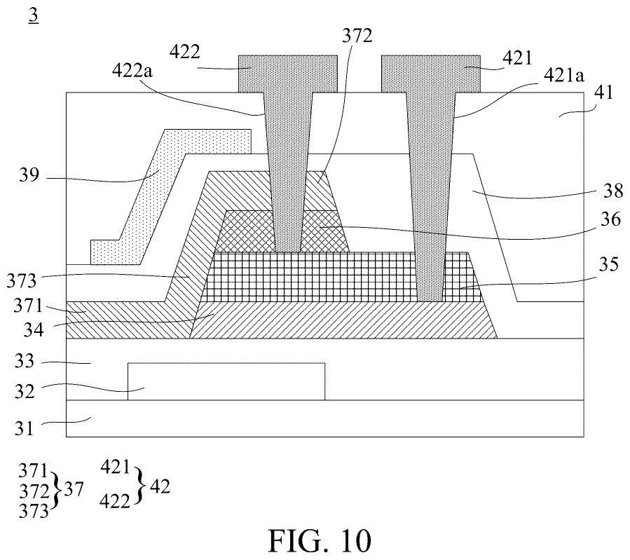

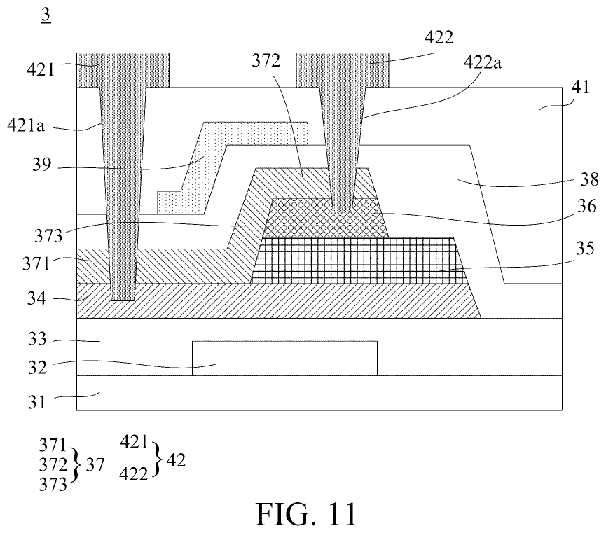

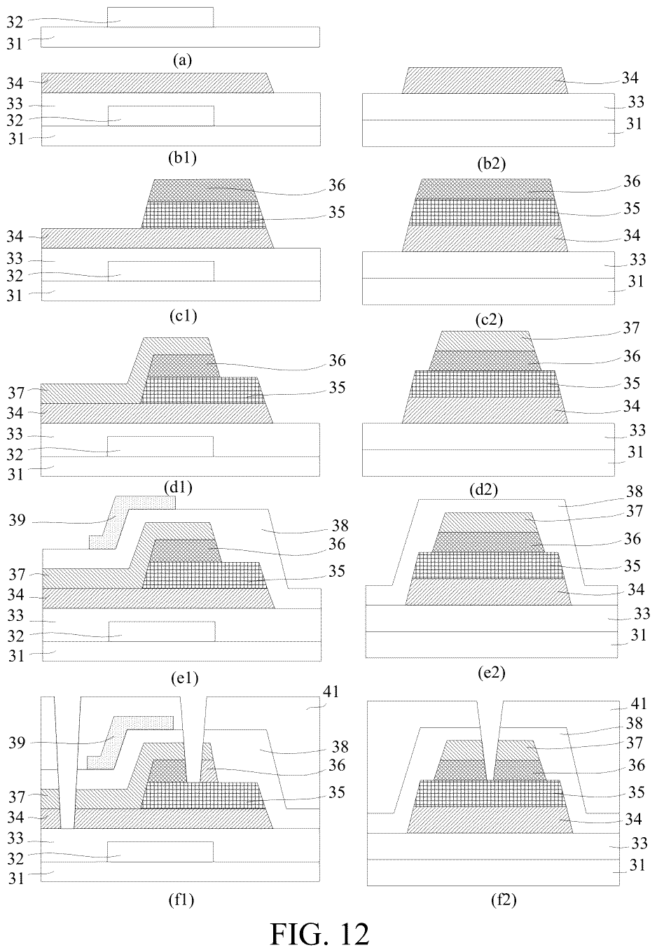

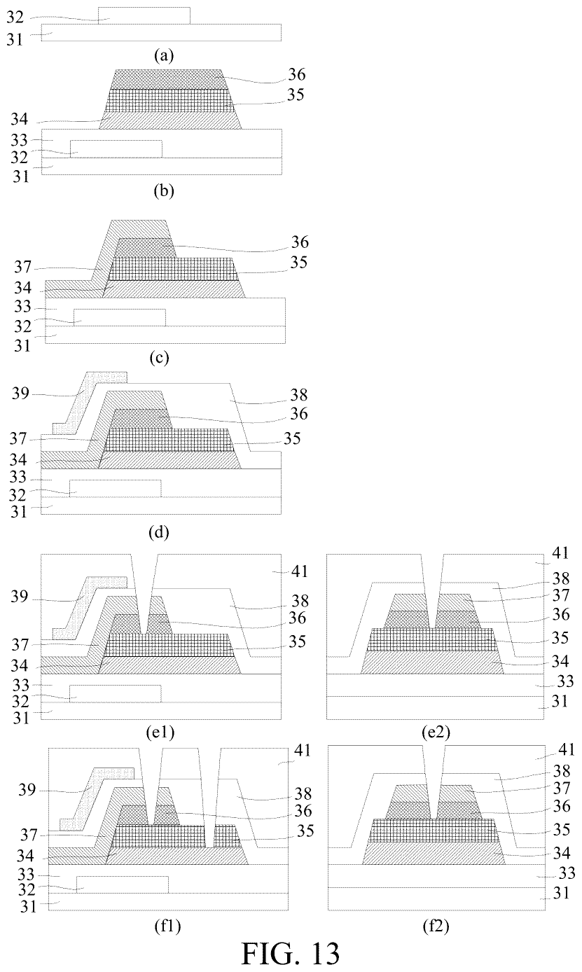

FIG. 4 is a top view of the first film layer structure of the thin film transistor provided by the embodiment of the present application. FIG. 5 is an exploded view of each film layer of the thin film transistor in FIG. 4. The section (a) in FIG. 5 is an exploded view of a first ohmic contact layer of the thin film transistor in FIG. 4. The section (b) in FIG. 5 is an exploded view of each film layer of the thin film transistor in FIG. 4. The section (c) in FIG. 5 is an exploded view of a second ohmic contact layer of the thin film transistor in FIG. 4. The section (d) in FIG. 5 is an exploded view of a channel layer of the thin film transistor in FIG. 4. The section (e) in FIG. 5 is an exploded view of a gate electrode layer of the thin film transistor in FIG. 4. FIG. 6 is a first cross-sectional view of the thin film transistor along a line B1-B2 in FIG. 4. FIG. 7 is a cross-sectional view of the thin film transistor along a line A1-A2 in FIG. 4. FIG. 8 is a top view of a second film layer structure of the thin film transistor provided by the embodiment of the present application. FIG. 9 is an exploded view of each film layer of the thin film transistor in FIG. 8. The section (a) in FIG. 9 is an exploded view of the first ohmic contact layer of the thin film transistor in FIG. 8. The section (b) in FIG. 9 is an exploded view of the barrier layer of the thin film transistor in FIG. 8. The section (c) in FIG. 9 is an exploded view of the second ohmic contact layer of the thin film transistor in FIG. 8. The section (d) in FIG. 9 is an exploded view of the channel layer of the thin film transistor in FIG. 8. The section (e) in FIG. 9 is an exploded view of the gate electrode layer of the thin film transistor in FIG. 8. FIG. 10 is a cross-sectional view of the thin film transistor along a line B1-B2 in FIG. 8. A cross-sectional view of the thin film transistor along the line A1-A2 in FIG. 8 is the same as that in FIG. 7. FIG. 11 is a second cross-sectional view of the thin film transistor along the line B1-B2 in FIG. 4. FIG. 12 is a schematic view of the structure of the film transistor corresponding to each step of the thin film transistor manufacturing method in FIG. 4. FIG. 13 is a schematic view of the structure of the film transistor corresponding to each step of the thin film transistor manufacturing method in FIG. 8.

With reference to FIG. 4 to FIG. 10, the embodiment of the present application provides a thin film transistor, the thin film transistor comprises:
an underlay substrate 31;
a first ohmic contact layer 34 disposed on a side of the underlay substrate 31;
a barrier layer 35 disposed on a side of the first ohmic contact layer 34 away from the underlay substrate 31, wherein the barrier layer 35 comprises at least one sidewall (for example, a sidewall of a left side in FIG. 6);
a second ohmic contact layer 36 disposed on a side of the barrier layer 35 away from the first ohmic contact layer 34;
a channel layer 37 comprising a first connection part 371, a second connection part 372, and an effective part 373 located on a sidewall, wherein the first connection part 371 contacts the first ohmic contact layer 34, and the second connection part 372 is disposed on the second ohmic contact layer 36;
a gate electrode insulation layer 38 disposed on a side of the channel layer 37 away from the second ohmic contact layer 36;
a gate electrode layer 39 disposed on a side of the gate electrode insulation layer 38 away from the channel layer 37, wherein an orthographic projection of the gate electrode layer 39 along a direction perpendicular to the underlay substrate 31 covers the effective part 373;
an interlayer insulation layer 41 disposed on a side of the gate electrode layer 39 away from the gate electrode insulation layer 38;
a source and drain electrode layer 42 disposed on a side of the interlayer insulation layer 41 away from the gate electrode layer 39, wherein the source and drain electrode layer 42 comprises a first electrode 421 and a second electrode 422;
wherein the second electrode 422 extends through the channel layer 37 and contacts the second ohmic contact layer 36;
and/or, the first electrode 421 extends through the barrier layer 35 and contacts the first ohmic contact layer 34;
or, the first connection part 371 is disposed on the first ohmic contact layer 34, and the first electrode 421 extends through the channel layer 37 and contacts the first ohmic contact layer 34.

The embodiment of the present application provides a thin film transistor, the thin film transistor disposes the effective part on the sidewall of the barrier layer, with the first connection part and the second connection part respectively contacting the first ohmic contact layer and the second ohmic contact layer located on a top and a bottom of the barrier layer, respectively. The above configuration allows control of the channel length through the thickness and angle of the barrier layer, using a conventional process to reduce the channel length, decrease the volume of the thin-film transistor, and improve mobility. Additionally, by having the second electrode extending through the channel layer and contacting the second ohmic contact layer, even if the second ohmic contact layer is over-etched, the second electrode can still function properly with the second ohmic contact layer. Furthermore, the first electrode may extend through the barrier layer and contact the first ohmic contact layer, or extend through the channel layer and contact the first ohmic contact layer, ensuring that even if the first ohmic contact layer is over-etched, the first electrode can still function properly with the first ohmic contact layer. This improves the yield of the display panel and reduces the size of the thin-film transistor.

In particular, conditions that the second electrode extends through the channel layer and contacts the second ohmic contact layer; and/or the first electrode extends through the barrier layer and contacts the first ohmic contact layer; or, the first connection part is disposed on the second ohmic contact layer, the first electrode extends through the channel layer and contacts the first ohmic contact layer, comprises at least one of the following technical solutions:

The second electrode extends through the channel layer and contacts the second ohmic contact layer, and no limitation is set to the configuration of the first electrode. The first electrode extends through the barrier layer and contacts the first ohmic contact layer, and no limitation is set to the configuration of the second electrode. The first connection part is disposed on the second ohmic contact layer, the first electrode extends through the channel layer and contacts the first ohmic contact layer, and no limitation is set to the configuration of the second electrode. The second electrode extends through the second ohmic contact layer for contact, and the first electrode extends through the barrier layer and contacts the first ohmic contact layer. The second electrode extends through the second ohmic contact layer for contact, and the first connection part is disposed on the second ohmic contact layer, the first electrode extends through the channel layer and contacts the first ohmic contact layer.

In particular, in FIG. 4 and FIG. 8 a reference numeral 43 is used to refer to a location of the via hole, a film layer penetrated by the via hole is based on an actual design. For example, in FIG. 4, a via hole extends through the interlayer insulation layer 41, the gate electrode insulation layer 38, the channel layer 37, and the first ohmic contact layer 34. Another via hole extends through the interlayer insulation layer 41, the gate electrode insulation layer 38, the channel layer 37, and the second ohmic contact layer 36. Each connection hole is used to particularly describe the configuration of the via hole in the following embodiment.

In some embodiments, when the second electrode extends through the channel layer and contacts the second ohmic contact layer, in a contact surface between the second ohmic contact layer and the second connection part, an upper surface of the second ohmic contact layer coincides with a lower surface of the second connection part, and slopes of three side surfaces in the second ohmic contact layer not contacting the effective part are equal to a slope corresponding to the second connection part.

In some embodiments, in a contact surface between the first ohmic contact layer and the barrier layer, an upper surface of the first ohmic contact layer coincides with a lower surface of the barrier layer, and a slope of any side surface of the first ohmic contact layer is equal to a slope corresponding to a side surface of the barrier layer.

In some embodiments, a slope of one of the side surfaces of the first ohmic contact layer is equal to a slope of a side surface of the first connection part.

In some embodiments, the thin film transistor comprises a first connection hole, the first connection hole at least penetrates an interlayer insulation layer and a gate electrode insulation layer. and the first electrode contacts the first ohmic contact layer through the first connection hole.

In some embodiments, the first connection hole further penetrates the barrier layer; or the first connection hole penetrates the barrier layer and the first ohmic contact layer.

In some embodiments, the first connection hole further penetrates the first connection part; or the first connection hole penetrates the first connection part and the first ohmic contact layer.

In some embodiments, the thin film transistor comprises a second connection hole, the second connection hole at least penetrates the interlayer insulation layer, a gate electrode insulation layer, and a second connection part, and the second electrode contacts the second ohmic contact layer through the second connection hole.

In some embodiments, the second connection hole further penetrates the second connection part.

In some embodiments, along a horizontal direction, a width of the second connection part is less than a width of the barrier layer, in a region where the barrier layer extends beyond the second connection part, the first electrode contacts the first ohmic contact layer.

In some embodiments, a ratio of an ion doping concentration of the first ohmic contact layer to an ion doping concentration of the channel layer is greater than or equal to 10⁵.

In some embodiments, material of the channel layer comprises intrinsic silicon.

In some embodiments, as shown in FIG. 6, when the second electrode 422 extends through the channel layer 37 and contacts the second ohmic contact layer 36, in a contact surface between the second ohmic contact layer 36 and the second connection part 372, an upper surface of the second ohmic contact layer 36 coincides with a lower surface of the second connection part 372, and a slope of three side surfaces in the second ohmic contact layer 36 not contacting the effective part 373 is equal to a slope corresponding to the second connection part 372. The upper surface of the second ohmic contact layer coincides with the lower surface of the second connection part, a slope of three side surfaces of the second ohmic contact layer not contacting the effective part is equal to a slope of the second connection part, thereby removing a portion of the second ohmic contact layer extending beyond the channel layer, lowering process difficulty, and etching the channel layer and the second ohmic contact layer by adopting the same mask. Also, the second electrode extends through the channel layer and contacts the second ohmic contact layer such that the second electrode normally contacts and connect withs the second ohmic contact layer, and the second electrode and the second ohmic contact layer normally work, thereby improving the yield of the thin film transistor.

In particular, as shown in FIG. 6, an end portion of the second ohmic contact layer 36 (for example, The right end of FIG. 6) and an end portion of the channel layer 37 (for example, The right end of FIG. 6) are located in the same plane, and the second electrode 422 extends through the channel layer 37 and contacts the second ohmic contact layer 36. An end portion of the second ohmic contact layer and an end portion of the channel layer are located in the same plane, thereby removing a portion of the second ohmic contact layer extending beyond the channel layer, lowering process difficulty, and improving the yield of the thin film transistor. Also, the second electrode extends through the channel layer and contacts the second ohmic contact layer such that the second electrode normally contacts and connect withs the second ohmic contact layer, and the second electrode and the second ohmic contact layer normally work.

In particular, compared to the current display device required to reserve the portion of the second ohmic contact layer extending beyond the channel in the channel etching process, the embodiment of the present application is not required to reserve the portion of the second ohmic contact layer extending beyond the channel layer such that the process difficulty can be lowered during etching the channel layer of the thin film transistor. Also, the second electrode extends through the channel layer and is connected to the second ohmic contact layer such that the second electrode can still transmit signals to the second ohmic contact layer without reserving the portion of the second ohmic contact layer extending beyond the channel layer, thereby being able to reduce the volume of the thin film transistor. Also, because the signal is still transmitted from the second ohmic contact layer to the channel layer, the channel length still can be controlled by the thickness and the angle the of the barrier layer, thereby being able to improve the mobility of the thin film transistor, lowering process difficulty and improving the yield of the thin film transistor while the mobility of the thin film transistor keeps unchanged, and reducing the volume of the thin film transistor.

In particular, during designing the second electrode and the second ohmic contact layer, no change is needed for the design of the first electrode and the first ohmic contact layer such that the first electrode and first ohmic contact layer still adopt a configuration extending beyond the barrier layer. For example, the first electrode and the first ohmic contact layer adopts the design of the source and drain electrode layer and the first contact layer in FIG. 3.

In particular, an end portion of the first ohmic contact layer 34 and an end portion of the barrier layer 35 located in the same plane refers to that a side of the first ohmic contact layer and a side of the barrier layer can be etched by the same mask such that in the etched first ohmic contact layer and the etched barrier layer, an end portion of the first ohmic contact layer and an end portion of the barrier layer are located in the same inclined plane or vertical plane, thereby removing the first ohmic contact layer extending beyond the barrier layer and the channel layer. Similarly, an end portion of the second ohmic contact layer and an end portion of the channel layer located in the same plane refers to that an end portion of the second ohmic contact layer and an end portion of the barrier layer are located in the same inclined plane or vertical plane. An end portion of the first ohmic contact layer and an end portion of the channel layer located in the same plane refers to that an end portion of the first ohmic contact layer and an end portion of the channel layer are located in the same inclined plane or vertical plane.

In particular, the attached drawings of the embodiment of the present application provide explanative illustration by end portions of two film layers being inclined planes or vertical planes. It can be understood that end portions of any two contacting film layers can be inclined planes or vertical planes, and the attached drawings of the embodiment of the present application do not show all of designs.

It should be explained that in an actual process, it is considered that etching instability probably occurs at end portions of two film layers instead of being at the same plane, for example, an end portion of the first ohmic contact layer and an end portion of the barrier layer, due to limitations of the process, have a difference between angles of the end portions of the first ohmic contact layer and the barrier layer, or staggered portions occur at the end portions of the first ohmic contact layer and the barrier layer. However, it is still deemed that an end portion of the first ohmic contact layer and an end portion of the barrier layer are located in the same plane, and only the slight difference occurs due to manufacturing process errors.

In some embodiments, as shown in FIG. 10, on the contact surface between the first ohmic contact layer 34 and the barrier layer 35, an upper surface of the first ohmic contact layer 34 coincides with a lower surface of the barrier layer 35, and a slope of any one of side surfaces of the first ohmic contact layer 34 is equal to a slope of a side surface corresponding to the barrier layer 35. The upper surface of the first ohmic contact layer coincides with the lower surface of the barrier layer, and the slope of any one of the side surfaces of the first ohmic contact layer is equal to the slope of the side surface corresponding to the barrier layer such that the first ohmic contact layer would not extend beyond the barrier layer, thereby removing the portion of the first ohmic contact layer extending beyond the channel layer and the barrier layer, and lowering the process difficulty. Also, the first electrode can extend through the barrier layer and contact the first ohmic contact layer such that the first electrode normally contacts and connects with the first ohmic contact layer, and the first electrode and the first ohmic contact layer normally work, thereby improving the yield of the thin film transistor.

In particular, as shown in FIG. 10, an end portion of the first ohmic contact layer 34 (for example, the right end in FIG. 10) and an end portion of the barrier layer 35 (for example, the right end in FIG. 10) are located in the same plane, another end portion of the first ohmic contact layer 34 (for example, the left end in FIG. 10) and another end portion of the barrier layer 35 (for example, the left end in FIG. 10) are located in the same plane, and the first electrode 421 extends through the barrier layer 35 and contacts the first ohmic contact layer 34. An end portion of the first ohmic contact layer and an end portion of the barrier layer are located in the same plane, another end portion of the first ohmic contact layer and another end portion of the barrier layer are located in the same plane, then the first ohmic contact layer would not extend beyond the barrier layer, thereby removing the portion of the first ohmic contact layer extending beyond the channel layer and the barrier layer, lowering the process difficulty, and improving the yield of the thin film transistor. Also, the first electrode extends through the barrier layer and contacts the first ohmic contact layer such that the first electrode normally contacts and connects with the first ohmic contact layer, and the first electrode and the first ohmic contact layer normally work.

In particular, compared to the channel etching process in the current display device required to reserve the portion of the first ohmic contact layer extending beyond the channel and the barrier layer, the embodiment of the present application is not required to reserve the portion of the first ohmic contact layer extending beyond the channel layer and the barrier layer, thereby being able to lower the process difficulty during etching the channel layer of the thin film transistor. Also, by the first electrode extending through the barrier layer and connected to the first ohmic contact layer, the first electrode can still transmit signals to the first ohmic contact layer without reserving the portion of the first ohmic contact layer extending beyond the channel layer and the barrier layer in advance, thereby being able to reduce the volume of the thin film transistor. Also, because the signal is still transmitted from the first ohmic contact layer to the channel layer, the channel length can still be controlled by the thickness and the angle of the barrier layer, thereby improving the mobility of the thin film transistor, lowering the process difficulty, improving the yield of the thin film transistor, and reducing the volume of the thin film transistor while keeping the mobility of the thin film transistor unchanged.

In particular, during designing the first electrode and first ohmic contact layer, no change is needed for the design of the second electrode and the second ohmic contact layer such that the second electrode and the second ohmic contact layer still adopt the configuration of extending beyond the channel layer. For example, the second electrode and the second ohmic contact layer adopt the design of the source and drain electrode layer in FIG. 3 and the second contact layer in FIG. 2.

In some embodiments, as shown in FIG. 6, a slope of a side surface in the first ohmic contact layer 34 is equal to a slope of a side surface of the first connection part 371. A slope of one side surface of first ohmic contact layer is equal to a slope of a side surface of the first connection part such that the first ohmic contact layer would not extend beyond the channel layer, thereby removing the portion of the first ohmic contact layer extending beyond the channel layer and lowering the process difficulty. Also, the first electrode extends through the channel layer and contacts the first ohmic contact layer such that the first electrode normally contacts and connects with the first ohmic contact layer, and the first electrode and the first ohmic contact layer normally work, thereby improving the yield of the thin film transistor.

In particular, as shown in FIG. 6, the end portion of the first ohmic contact layer 34 (for example, the right end in FIG. 6) and the end portion of the barrier layer 35 (for example, the right end in FIG. 6) are located in the same plane, another end portion of the first ohmic contact layer 34 (for example, The left end in FIG. 6) and another end portion of the channel layer 37 (for example, The left end in FIG. 6) are located in the same plane. The first electrode 421 extends through the channel layer 37 and contacts the first ohmic contact layer 34. An end portion of the first ohmic contact layer and an end portion of the barrier layer are located in the same plane, and another end portion of the first ohmic contact layer and another end portion of the channel layer are located in the same plane such that the first ohmic contact layer would not extend beyond the barrier layer and the channel layer, thereby removing the portion of the first ohmic contact layer extending beyond the channel layer and the barrier layer, lowering the process difficulty, and improving the yield of the thin film transistor. Also, the first electrode extends through the channel layer and contacts the first ohmic contact layer such that the first electrode normally contacts and connects with the first ohmic contact layer, and the first electrode and the first ohmic contact layer normally work.

In particular, compared to the channel etching process in the current display device required to reserve the portion of the first ohmic contact layer extending beyond the channel and the barrier layer, the embodiment of the present application is not required to reserve the portion of the first ohmic contact layer extending beyond the channel layer and the barrier layer, thereby being able to lower the process difficulty during etching the channel layer of the thin film transistor. Also, by the first electrode extending through the barrier layer and connected to the first ohmic contact layer, the first electrode can still transmit signals to the first ohmic contact layer without reserving the portion of the first ohmic contact layer extending beyond the channel layer and the barrier layer in advance, thereby being able to reduce the volume of the thin film transistor. Also, because the signal is still transmitted from the first ohmic contact layer to the channel layer, the channel length can still be controlled by the thickness and the angle of the barrier layer, thereby improving the mobility of the thin film transistor, lowering the process difficulty, improving the yield of the thin film transistor, and reducing the volume of the thin film transistor while keeping the mobility of the thin film transistor unchanged.

In particular, during designing the first electrode and first ohmic contact layer, no change is needed for the design of the second electrode and the second ohmic contact layer such that the second electrode and the second ohmic contact layer still adopt the configuration of extending beyond the channel layer. For example, the second electrode and the second ohmic contact layer adopt the design of the source and drain electrode layer in FIG. 3 and the second contact layer in FIG. 2.

In some embodiments, as shown in FIG. 6, the thin film transistor 3 comprises a first connection hole 421a, the first connection hole 421a at least penetrates the interlayer insulation layer 41 and the gate electrode insulation layer 38, and the first electrode 421 extends through the first connection hole 421a and contacts the first ohmic contact layer 34.

In some embodiments, with reference to FIG. 10, the first connection hole 421a further penetrates the barrier layer 35; or the first connection hole 421a penetrates the barrier layer 35 and the first ohmic contact layer 34. The first connection hole penetrates the barrier layer such that a contact surface area between the first electrode and the first ohmic contact layer is greater, and contact stability between the first electrode and the first ohmic contact layer is better. The first connection hole penetrates the barrier layer and the first ohmic contact layer such that the first electrode annularly contacts the first ohmic contact layer. Therefore, during etching the channel layer, the first ohmic contact layer 34 is also being etched simultaneously, thereby preventing the first electrode 421 unable to contact the first ohmic contact layer 34 or poor contact therebetween and improving the yield of the thin film transistor.

In some embodiments, the first connection hole 421a further penetrates the first connection part 371. Alternatively, as shown in FIG. 6, the first connection hole 421a penetrates the first connection part 371 and the first ohmic contact layer 34. The first connection hole penetrates the first connection part such that a contact surface area between the first electrode and the first ohmic contact layer is greater, and a contact stability between the first electrode and the first ohmic contact layer is better. The first connection hole penetrates the first connection part and the first ohmic contact layer such that the first electrode annularly contacts the first ohmic contact layer. Therefore, during etching during etching the channel layer, the first ohmic contact layer 34 is also being etched simultaneously, thereby preventing the first electrode 421 unable to contact the first ohmic contact layer 34 or poor contact therebetween and improving the yield of the thin film transistor.

In particular, as shown in FIG. 6, the end portion of the first ohmic contact layer 34 (for example, the right end in FIG. 6) and the end portion of the barrier layer 35 (for example, the right end in FIG. 6) are located in the same plane, another end portion of the first ohmic contact layer 34 (for example, The left end in FIG. 6) and another end portion of the channel layer 37 (for example, The left end in FIG. 6) are located in the same plane. In a contact surface between the first ohmic contact layer 34 and the channel layer 37, the first electrode 421 contacts the first ohmic contact layer 34. Alternatively, as shown in FIG. 6, the first electrode 421 extends through the first ohmic contact layer 34, the first electrode 421 annularly contacts the first ohmic contact layer 34.

In particular, the first electrode contacts the first ohmic contact layer on the contact surface between the first ohmic contact layer and the channel layer such that the contact surface area between the first electrode and the first ohmic contact layer is greater, and the contact stability of the first electrode and the first ohmic contact layer is better.

In particular, the material of the channel layer and the material of the first ohmic contact layer are the same and the dry etching process does not provide a selection ratio, reserving the first ohmic contact layer probably results in the channel layer etched incompletely during etching the channel layer, thereby causing the first ohmic contact layer not to contact the first electrode or a poor contact effect. The embodiment of the present application enables the first electrode 421 to extend through the first ohmic contact layer 34 and the first electrode 421 to annularly contact the first ohmic contact layer 34. Therefore, the first ohmic contact layer 34 is also being etched simultaneously during etching the channel layer, thereby preventing the first electrode 421 unable to contact the first ohmic contact layer 34 or poor contact therebetween, and improving the yield of the thin film transistor.

In particular, as shown in FIG. 10, the end portion of the first ohmic contact layer 34 (for example, the right end in FIG. 10) and the end portion of the barrier layer 35 (for example, the right end in FIG. 10) are located in the same plane, and another end portion of the first ohmic contact layer 34 (for example, the left end in FIG. 10) and another end portion of the barrier layer 35 (for example, the left end in FIG. 10) are located in the same plane. In a portion of the barrier layer 35 extends beyond the second ohmic contact layer 36, the first electrode 421 extends through the barrier layer 35 and contacts the first ohmic contact layer 34, and an interval is between the first electrode 421 and the second ohmic contact layer 36. An end portion of the first ohmic contact layer and an end portion of the barrier layer are located in the same plane, another end portion of the first ohmic contact layer and another end portion of the barrier layer are located in the same plane, then the first ohmic contact layer would not extend beyond the barrier layer, thereby removing the portion of the first ohmic contact layer extending beyond the channel layer and the barrier layer, lowering the process difficulty, and improving the yield of the thin film transistor. Also, the first electrode can extend through barrier layer by extending through the portion of the barrier layer extending beyond the second ohmic contact layer and contact the first ohmic contact layer, and can reduce a size of the thin film transistor, such that the first electrode normally contacts and connects with the first ohmic contact layer, and the first electrode and the first ohmic contact layer normally work.

In particular, compared to the first electrode extending through the channel layer and connected to the first ohmic contact layer, the first electrode extending through a part of the barrier layer extending beyond the second ohmic contact layer can further reduce a size of the thin film transistor.

In some embodiments, as shown in FIG. 10, on the contact surface between the first ohmic contact layer 34 and the barrier layer 35, the first electrode 421 contacts the first ohmic contact layer 34. The first electrode contacts the first ohmic contact layer on the contact surface between the first ohmic contact layer and barrier layer such that the contact surface area between the first electrode and the first ohmic contact layer is greater and has better stability.

In particular, because the material of the first ohmic contact layer is different from the material of the barrier layer, when a dry etching process is implemented on the barrier layer, a selection ratio can exist such that only the barrier layer is etched without etching the first ohmic contact layer, thereby making the contact surface area between the first electrode and the first ohmic contact layer greater and having better stability and improving the yield of the thin film transistor.

In particular, the first electrode extends through the first ohmic contact layer, and the first electrode annularly contacts the first ohmic contact layer. When the first electrode contacts the first ohmic contact layer, the first electrode can extend through the first ohmic contact layer and annularly contact the first ohmic contact layer as well.

The above embodiment utilizes the first electrode penetrating the first ohmic contact layer as an example for explanation, but the embodiment of the present application is not limited thereto. For example, as shown in FIG. 11, a depth of the via hole of the first ohmic contact layer can be one-tenth to nine-tenth of the thickness of the first ohmic contact layer, and the process can be implemented by controlling the etching time, namely, the etching time is guaranteed to be greater than the time required for etching the channel layer, and the process difficulty is lower.

In some embodiments, as shown in FIG. 6, the thin film transistor 3 comprises a second connection hole 422a, and the second connection hole 422a at least penetrates the interlayer insulation layer 41, the gate electrode insulation layer 38, and the second connection part 372. The second electrode 422 contacts the second ohmic contact layer 36 through the second connection hole 422a. The second connection hole penetrates the interlayer insulation layer, the gate electrode insulation layer, and the second connection part such that the second electrode can contact the second ohmic contact layer, and the second electrode can be connected normally to the second ohmic contact layer.

In some embodiments, as shown in FIG. 6, the second connection hole further penetrates the second connection part.

In some embodiments, on the contact surface between the second ohmic contact layer 36 and the channel layer 37, the second electrode 422 contacts the second ohmic contact layer 36. Alternatively, as shown in FIG. 6, the second electrode 422 extends through the second ohmic contact layer 36 and the second electrode 422 and annularly contacts the second ohmic contact layer 36.

In particular, the second electrode contacts the second ohmic contact layer on the contact surface between the second ohmic contact layer and the channel layer such that the contact surface area between the second electrode and the second ohmic contact layer is greater, and the contact stability of the second electrode and the second ohmic contact layer is better.

In particular, the material of the channel layer and the material of the second ohmic contact layer are the same and the dry etching process does not provide a selection ratio, thereby causing the second ohmic contact layer not to contact the second electrode or a poor contact effect. The embodiment of the present application enables the second electrode 422 to extend through the second ohmic contact layer 36 and the second electrode 422 and annularly contact the second ohmic contact layer 36. Therefore, the second ohmic contact layer 36 is also etched simultaneously during etching the channel layer, thereby preventing the second electrode 422 unable to contact the second ohmic contact layer 36 or poor contact therebetween, and improving the yield of the thin film transistor.

The above embodiment utilizes the second electrode penetrating the second ohmic contact layer as an example for explanation, but the embodiment of the present application is not limited thereto. For example, as shown in FIG. 11, a depth of the thickness of the second ohmic contact layer can be one-tenth to nine-tenth the thickness of the second ohmic contact layer, and the process can be implemented by controlling the etching time, namely, the etching time is guaranteed to be greater than the time required for etching the channel layer, and the process difficulty is lower.

In some embodiments, as shown in FIG. 10, along a horizontal direction, a width of the second connection part 372 is less than a width of the barrier layer 35, in a region of the barrier layer 35 extending beyond the second connection part 372, the first electrode 421 contacts the first ohmic contact layer 34. The width of the barrier layer is greater than the width of the second connection part and a least a part of the barrier layer extends beyond the second ohmic contact layer such that the first electrode can extend through the barrier layer and be connected to the first ohmic contact layer, thereby reducing the volume of the thin film transistor.

Regarding the issue that the first electrode and/or the second electrode directly contacting the channel layer probably results in the thin film transistor keeping constantly in a switching-on state, in some embodiments, a ratio of an ion doping concentration of the first ohmic contact layer to an ion doping concentration of the channel layer is greater than or equal to 10⁵. The ion doping concentration of the channel layer is five orders of magnitude less than the ion doping concentration of the first ohmic contact layer such that the ion doping concentration of the channel layer is lower. The channel layer is nearly insulative material, the thin film transistor would not be constantly in the switching-on state, an electrical signal would still be transmitted from the first electrode to the first ohmic contact layer, the first ohmic contact layer transmits the electrical signal from the channel layer to the second ohmic contact layer, and the electrical signal is transmitted from the second ohmic contact layer to the second electrode such that the channel length can still be controlled by the thickness and the angle of the barrier layer, thereby lowering the channel length and improving the mobility of the thin film transistor.

In particular, the ion doping concentration is an ion doping concentration of a unit area.

In particular, a difference between the ion doping concentration of the first ohmic contact layer and an ion doping concentration of the second ohmic contact layer is less than one order of magnitude. More in particular, the ion doping concentration of the first ohmic contact layer is equal to the ion doping concentration of the second ohmic contact layer.

In some embodiments, material of the channel layer comprises intrinsic silicon. The material of the channel layer of intrinsic silicon can further improve insulation of the channel layer, thereby preventing the thin film transistor from constantly in the switching-on state and improving the yield of the thin film transistor.

In particular, material of the channel layer comprises polycrystalline silicon.

In some embodiments, material of the first ohmic contact layer comprises polycrystalline silicon.

In some embodiments, material of the second ohmic contact layer comprises polycrystalline silicon.

In some embodiments, material of the barrier layer comprises silicon oxide.

In some embodiments, as shown in FIG. 6, thin film transistor 3 further comprises a light shielding layer 32, a buffer layer 33, a gate electrode insulation layer 38, and an interlayer insulation layer 41.

In some embodiments, the first electrode is a source electrode, the second electrode is a drain electrode. Alternatively, the first electrode is a drain electrode, the second electrode is a source electrode.

The above embodiment describes the thin film transistor according to the connection relationship between the film layers, each film layer. It can be understood that when no conflict is between embodiments, the embodiment can be combined to achieve better technical effect, or to perform complete description to the embodiments. For example, to further lower the process difficulty, reducing the volume of the thin film transistor makes the following configuration: an end portion of the second ohmic contact layer and an end portion of the channel layer are located in the same plane, the second electrode extends through the channel layer and contacts the second ohmic contact layer, and an end portion of the first ohmic contact layer and an end portion of the barrier layer are located in the same plane, another end portion of the first ohmic contact layer and another end portion of the barrier layer are located in the same plane, and the first electrode extends through the barrier layer and contacts the first ohmic contact layer. Alternatively, an end portion of the second ohmic contact layer and an end portion of the channel layer are located in the same plane, the second electrode extends through the channel layer and contacts the second ohmic contact layer, an end portion of the first ohmic contact layer and an end portion of the barrier layer are located in the same plane, another end portion of the first ohmic contact layer and another end portion of the channel layer are located in the same plane, and the first electrode extends through the channel layer and contacts the first ohmic contact layer.

Also, the embodiment of the present application provides a thin film transistor manufacturing method, and the thin film transistor manufacturing method manufactures any one of the thin film transistors of the above embodiments.

In particular, a thin film transistor manufacturing method comprises:
providing an underlay substrate; the structure of the thin film transistor corresponding to the step is as shown in the section (a) in FIG. 12;
forming a light shielding layer on the underlay substrate; the structure of the thin film transistor corresponding to the step is as shown in the section (a) in FIG. 12;
sequentially forming a buffer layer and a the first ohmic contact layer on the light shielding layer; a cross-sectional view of the thin film transistor corresponding to the step along the line B1-B2 is as shown in the section (b1) in FIG. 12, a cross-sectional view of the thin film transistor corresponding to the step along the line A1-A2 is as shown in the section (b2) in FIG. 12;
forming a barrier layer and a second ohmic contact layer on the first ohmic contact layer; the cross-sectional view of the thin film transistor corresponding to the step along the line B1-B2 is as shown in the section (c1) in FIG. 12, and the cross-sectional view of the thin film transistor corresponding to the step along the line A1-A2 is as shown in the section (c2) in FIG. 12;
forming a channel layer on the second ohmic contact layer, and etching the channel layer and the second ohmic contact layer. The cross-sectional view of the thin film transistor corresponding to the step along the line B1-B2 is as shown in the section (d1) in FIG. 12, and the cross-sectional view of the thin film transistor corresponding to the step along the line A1-A2 is as shown in FIG. 12 [symbol] (d2);
forming a gate electrode insulation layer and a gate electrode layer on the channel layer; the cross-sectional view of the thin film transistor corresponding to the step along the line B1-B2 is as shown in the section (e1) in FIG. 12, and the cross-sectional view of the thin film transistor corresponding to the step along the line A1-A2 is as shown in the section (e2) in FIG. 12;
forming an interlayer insulation layer on the gate electrode layer, and etching the interlayer insulation layer, the gate electrode insulation layer, the channel layer, the first ohmic contact layer, and the second ohmic contact layer to form a via hole; the cross-sectional view of the thin film transistor corresponding to the step along the line B1-B2 is as shown in the section (f1) in FIG. 12, and the cross-sectional view of the thin film transistor corresponding to the step along the line A1-A2 is as shown in the section (f2) in FIG. 12;
forming a source and drain electrode layer on the interlayer insulation layer; the cross-sectional view of the thin film transistor corresponding to the step along the line B1-B2 is as shown in FIG. 6, and the cross-sectional view of the thin film transistor corresponding to the step along the line A1-A2 is as shown in FIG. 7.

In particular, another thin film transistor manufacturing method comprises:
providing an underlay substrate; the structure of the thin film transistor corresponding to the step is as shown in the section (a) in FIG. 13;
forming a light shielding layer on the underlay substrate; the structure of the thin film transistor corresponding to the step is as shown in the section (a) in FIG. 13;
sequentially forming a buffer layer, a first ohmic contact layer, a barrier layer, and a second ohmic contact layer on the light shielding layer; the structure of the thin film transistor corresponding to the step is as shown in the section (b) in FIG. 13;
forming a channel layer on the second ohmic contact layer, and etching the channel layer and the second ohmic contact layer. The structure of the thin film transistor corresponding to the step is as shown in the section (c) in FIG. 13;
forming a gate electrode insulation layer and a gate electrode layer on the channel layer; the structure of the thin film transistor corresponding to the step is as shown in the section (d) in FIG. 13;
forming an interlayer insulation layer on the gate electrode layer, and etching the interlayer insulation layer, the gate electrode insulation layer, the channel layer, and the second ohmic contact layer to form a via hole; the cross-sectional view of the thin film transistor corresponding to the step along the line B1-B2 is as shown in the section (e1) in FIG. 13, and the cross-sectional view of the thin film transistor corresponding to the step along the line A1-A2 is as shown in the section (e2) in FIG. 13;
etching the interlayer insulation layer, the gate electrode insulation layer, and the barrier layer to form a via hole; the cross-sectional view of the thin film transistor corresponding to the step along the line B1-B2 is as shown in the section (f1) in FIG. 13, and the cross-sectional view of the thin film transistor corresponding to the step along the line A1-A2 is as shown in the section (f2) in FIG. 13;
forming a source and drain electrode layer on the interlayer insulation layer; a cross-sectional view of the thin film transistor corresponding to the step is along the line B1-B2 as shown in FIG. 10, a cross-sectional view of the thin film transistor corresponding to the step is along the line A1-A2 as shown in FIG. 7.

Also, the embodiment of the present application provides an electronic device, and the electronic device comprises any one of the thin film transistors of the above embodiments.

It can be understood according to the above embodiment that:

The embodiment of the present application provides a thin film transistor and an electronic device. The thin film transistor comprises an underlay substrate, a first ohmic contact layer, a barrier layer, a second ohmic contact layer, a channel layer, a gate electrode insulation layer, a gate electrode layer, an interlayer insulation layer, and a source and drain electrode layer. The first ohmic contact layer is disposed on a side of the underlay substrate. The barrier layer is disposed on a side of the first ohmic contact layer away from the underlay substrate. The barrier layer comprises at least one sidewall. The second ohmic contact layer is disposed on a side of the barrier layer away from the first ohmic contact layer. The channel layer comprises a first connection part, a second connection part and an effective part located on the sidewall. The first connection part contacts the first ohmic contact layer. The second connection part is disposed on the second ohmic contact layer. The gate electrode insulation layer is disposed on a side of the channel layer away from the second ohmic contact layer. The gate electrode layer is disposed on a side of the gate electrode insulation layer away from the channel layer. An orthographic projection of the gate electrode layer along a direction perpendicular to the underlay substrate direction covers the effective part. The interlayer insulation layer is disposed on a side of the gate electrode layer away from gate electrode insulation layer. The source and drain electrode layer is disposed on a side of the interlayer insulation layer away from gate electrode layer. The source and drain electrode layer comprises a first electrode and a second electrode. The second electrode extends through the channel layer and contacts the second ohmic contact layer; and/or, the first electrode extends through the barrier layer and contacts the first ohmic contact layer; or first connection part is disposed on the first ohmic contact layer, and the first electrode extends through the channel layer and contacts the first ohmic contact layer. The present application disposes the effective part on the sidewall of the barrier layer, with the first connection part and the second connection part respectively contacting the first ohmic contact layer and the second ohmic contact layer located on a top and a bottom of the barrier layer, respectively. The above configuration allows control of the channel length through the thickness and angle of the barrier layer, using a conventional process to reduce the channel length, decrease the volume of the thin-film transistor, and improve mobility. Additionally, by having the second electrode extending through the channel layer and contacting the second ohmic contact layer, even if the second ohmic contact layer is over-etched, the second electrode can still function properly with the second ohmic contact layer. Furthermore, the first electrode may extend through the barrier layer and contact the first ohmic contact layer, or extend through the channel layer and contact the first ohmic contact layer, ensuring that even if the first ohmic contact layer is over-etched, the first electrode can still function properly with the first ohmic contact layer. This improves the yield of the display panel and reduces the size of the thin-film transistor.

In the above-mentioned embodiments, the descriptions of the various embodiments are focused. For the details of the embodiments not described, reference may be made to the related descriptions of the other embodiments.

The thin film transistor and the electronic device provided by the embodiment of the present application are described in detail as above. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

1. A thin film transistor, comprising:
an underlay substrate;
a first ohmic contact layer disposed on a side of the underlay substrate;
a barrier layer disposed on a side of the first ohmic contact layer away from the underlay substrate, wherein the barrier layer comprises at least one sidewall;
a second ohmic contact layer disposed on a side of the barrier layer away from the first ohmic contact layer;
a channel layer comprising a first connection part, a second connection part, and an effective part located on the sidewall, wherein the first connection part contacts the first ohmic contact layer, and the second connection part is disposed on the second ohmic contact layer;
a gate electrode insulation layer disposed on a side of the channel layer away from the second ohmic contact layer;
a gate electrode layer disposed on a side of the gate electrode insulation layer away from the channel layer, wherein an orthographic projection of the gate electrode layer along a direction perpendicular to the underlay substrate direction covers the effective part;
an interlayer insulation layer disposed on a side of the gate electrode layer away from the gate electrode insulation layer;
a source and drain electrode layer disposed on a side of the interlayer insulation layer away from the gate electrode layer, wherein the source and drain electrode layer comprises a first electrode and a second electrode;
wherein the second electrode extends through the channel layer and contacts the second ohmic contact layer;
and/or, the first electrode extends through the barrier layer and contacts the first ohmic contact layer;
or, the first connection part is disposed on the first ohmic contact layer, and the first electrode extends through the channel layer and contacts the first ohmic contact layer.

2. The thin film transistor according to claim 1, wherein when the second electrode extends through the channel layer and contacts the second ohmic contact layer, in a contact surface between the second ohmic contact layer and the second connection part, an upper surface of the second ohmic contact layer coincides with a lower surface of the second connection part, and slopes of three side surfaces in the second ohmic contact layer not contacting the effective part are equal to a slope corresponding to the second connection part.

3. The thin film transistor according to claim 1, wherein in a contact surface between the first ohmic contact layer and the barrier layer, an upper surface of the first ohmic contact layer coincides with a lower surface of the barrier layer, and a slope of any side surface of the first ohmic contact layer is equal to a slope corresponding to a side surface of the barrier layer.

4. The thin film transistor according to claim 1, wherein a slope of one of the side surfaces of the first ohmic contact layer is equal to a slope of a side surface of the first connection part.

5. The thin film transistor according to claim 1, wherein the thin film transistor comprises a first connection hole, the first connection hole at least penetrates an interlayer insulation layer and a gate electrode insulation layer, and the first electrode contacts the first ohmic contact layer through the first connection hole.

6. The thin film transistor according to claim 5, wherein the first connection hole further penetrates the barrier layer; or the first connection hole penetrates the barrier layer and the first ohmic contact layer.

7. The thin film transistor according to claim 5, wherein the first connection hole further penetrates the first connection part; or the first connection hole penetrates the first connection part and the first ohmic contact layer.

8. The thin film transistor according to claim 1, wherein the thin film transistor comprises a second connection hole, the second connection hole at least penetrates the interlayer insulation layer, a gate electrode insulation layer, and a second connection part, and the second electrode contacts the second ohmic contact layer through the second connection hole.

9. The thin film transistor according to claim 8, wherein the second connection hole further penetrates the second connection part.

10. The thin film transistor according to claim 1, wherein along a horizontal direction, a width of the second connection part is less than a width of the barrier layer, in a region where the barrier layer extends beyond the second connection part, the first electrode contacts the first ohmic contact layer.

11. The thin film transistor according to claim 1, wherein a ratio of an ion doping concentration of the first ohmic contact layer to an ion doping concentration of the channel layer is greater than or equal to 10⁵.

12. The thin film transistor according to claim 1, wherein material of the channel layer comprises intrinsic silicon.

13. An electronic device, wherein the electronic device comprises a thin film transistor, and the thin film transistor comprises:
an underlay substrate;
a first ohmic contact layer disposed on a side of the underlay substrate;
a barrier layer disposed on a side of the first ohmic contact layer away from the underlay substrate, wherein the barrier layer comprises at least one sidewall;
a second ohmic contact layer disposed on a side of the barrier layer away from the first ohmic contact layer;
a channel layer comprising a first connection part, a second connection part, and an effective part located on the sidewall, wherein the first connection part contacts the first ohmic contact layer, and the second connection part is disposed on the second ohmic contact layer;
a gate electrode insulation layer disposed on a side of the channel layer away from the second ohmic contact layer;
a gate electrode layer disposed on a side of the gate electrode insulation layer away from the channel layer, wherein an orthographic projection of the gate electrode layer along a direction perpendicular to the underlay substrate direction covers the effective part;
an interlayer insulation layer disposed on a side of the gate electrode layer away from the gate electrode insulation layer;
a source and drain electrode layer disposed on a side of the interlayer insulation layer away from the gate electrode layer, wherein the source and drain electrode layer comprises a first electrode and a second electrode;
wherein the second electrode extends through the channel layer and contacts the second ohmic contact layer;
and/or, the first electrode extends through the barrier layer and contacts the first ohmic contact layer;
or, the first connection part is disposed on the first ohmic contact layer, and the first electrode extends through the channel layer and contacts the first ohmic contact layer.

14. The electronic device according to claim 13, wherein when the second electrode extends through the channel layer and contacts the second ohmic contact layer, in a contact surface between the second ohmic contact layer and the second connection part, an upper surface of the second ohmic contact layer coincides with a lower surface of the second connection part, and slopes of three side surfaces in the second ohmic contact layer not contacting the effective part are equal to a slope corresponding to the second connection part.

15. The electronic device according to claim 13, wherein in a contact surface between the first ohmic contact layer and the barrier layer, an upper surface of the first ohmic contact layer coincides with a lower surface of the barrier layer, and a slope of any side surface of the first ohmic contact layer is equal to a slope corresponding to a side surface of the barrier layer.

16. The electronic device according to claim 13, wherein a slope of one of the side surfaces of the first ohmic contact layer is equal to a slope of a side surface of the first connection part.

17. The electronic device according to claim 13, wherein the thin film transistor comprises a first connection hole, the first connection hole at least penetrates an interlayer insulation layer and a gate electrode insulation layer, and the first electrode contacts the first ohmic contact layer through the first connection hole.

18. The electronic device according to claim 17, wherein the first connection hole further penetrates the barrier layer; or the first connection hole penetrates the barrier layer and the first ohmic contact layer.

19. The electronic device according to claim 17, wherein the first connection hole further penetrates the first connection part; or the first connection hole penetrates the first connection part and the first ohmic contact layer.

20. The electronic device according to claim 13, wherein the thin film transistor comprises a second connection hole, the second connection hole at least penetrates the interlayer insulation layer, the gate electrode insulation layer, and the second connection part, and the second electrode contacts the second ohmic contact layer through the second connection hole.
